(19) United States
(12) Patent Application Publication
(10) Pub. No.: US 2024/0423065 A1
(43) Pub. Date: Dec. 19, 2024

(54) DISPLAY DEVICE

(71) Applicant: Wuhan China Star Optoelectronics Semiconductor Display Technology Co., Ltd., Wuhan (CN)

(72) Inventor: Huipeng Chen, Wuhan (CN)

(21) Appl. No.: 17/619,706

(22) PCT Filed: Dec. 7, 2021
(86) PCT No.: PCT/CN2021/136197

§ 371 Date: Sep. 2, 2024

(30) Foreign Application Priority Data
Nov. 29, 2021 (CN) 202122966385.5

(51) Int. Cl. H10K 59/80; G02F 1/1339

(52) U.S. Cl. CPC H10K 59/8722; G02F 1/1339

(57) ABSTRACT

A display device includes a backplate, a display panel, a polarizer, a protective layer, and an adhesive layer. A side of the adhesive layer near the backplate is attached to a side of the polarizer away from the backplate. A side of the adhesive layer away from the backplate is attached to a side of the protective layer near the backplate.

### FIELD OF THE DISCLOSURE

The present disclosure relates to the field of display technology, and more particularly, to a display device.

### DESCRIPTION OF THE RELATED ART

Owing to the continuous development and innovation of flexible display technology, a flexible display is rollable, which brings diversity and imagination to the appearance of a display product. A dynamic folding display device has gradually become a mainstream product.

The stack of the module of the dynamic folding display device of the related art is complicated. The attachment process for the module of the dynamic folding display device of the related art is quite a lot. Due to these reasons, the yield rate of the module of the related art is relatively low while the entire module is comparatively heavy. In addition, the material cost for the module of the related art is high so the module of the dynamic folding display device of the related art is quite expensive. For example, a plastic glass cover (colorless polyimide, CPI) is utilized in the module of the dynamic folding display device of the related art to strengthen the falling-ball and falling-pencil performance. An ultra-thin glass (UTG) is adopted in the module of the dynamic folding display device of the related art to improve the falling-ball and falling-pencil performance and the orange-peel effect.

### Technical Problem

The stack of the module of the dynamic folding display device and the fabrication process for the module of the dynamic folding display device are both complicated so the production cost and the material cost are both relatively high, which far exceeds most consumers' acceptance, resulting in the dynamic folding display device of the related art with low market share.

### Technical Solution

An object of the present disclosure to propose a display device to solve the problem of the display device of the related art, of which the shortcomings are low quality, heavy weight, high cost, and so on.

According to the present disclosure, a display device includes a backplate, a display panel disposed on the backplate, a polarizer disposed on a side of the display panel away from the backplate, a protective layer, disposed on a side of the polarizer away from the backplate, and an adhesive layer, disposed between the protective layer and the polarizer. A side of the adhesive layer near the backplate is attached to the polarizer away from the backplate. A side of the adhesive layer away from the backplate is attached to the protective layer near the backplate.

Furthermore, the protective layer is a plastic film layer.

Furthermore, a material for the protective layer comprises polyethylene terephthalate (PET), polyimide (PI), polyethylene (PE), or acrylic.

Furthermore, the thickness of the protective layer ranges from 30 to 150 micrometers (um).

Furthermore, the adhesive layer is an optical adhesive.

Furthermore, the display panel is either an organic light-emitting display panel or a liquid crystal display panel.

Furthermore, the display device further comprises a buffer layer disposed on a side of the backplate away from the display panel, and a supportive layer disposed on a side of the buffer layer away from the display panel.

Furthermore, the display device comprises a bending area and non-bending area. A plurality of holes are disposed on the supportive layer for the bending area.

Furthermore, the display device further comprises a sealing layer, covering the supportive layer for the bending area away from the backplate and extending to cover the supportive layer for the non-bending area away from the backplate.

Furthermore, a material for the buffer layer is selected from foam, polyimide (PI), polyethylene terephthalate (PET), and an optical adhesive.

### Beneficial Effect

In the present disclosure, the adhesive layer is disposed between the protective layer and the polarizer. A side of the adhesive layer near the backplate is attached to the polarizer away from the backplate. A side of the adhesive layer away from the backplate is attached to the protective layer near the backplate. In this way, the plastic glass cover (colorless polyimide, CPI) and the ultra-thin glass (UTG) in the display device of the related art are removed and are not utilized. Moreover, the display device of the present disclosure can increase the yield rate of the display device and reduce the weight of the display device on the basis of satisfaction of the requirement of the falling-ball and falling-pencil performance. It is also possible to reduce the cost on the material for the display device, to simplify the fabrication process of the display device, to improve the production efficiency of the display device, to reduce the production cost of the display device, and further, the price of the display device is lowered. Accordingly, more and more consumers accept the display device proposed by the present embodiment, and market share increases.

### BRIEF DESCRIPTION OF THE DRAWINGS

To describe the technical solutions in the embodiments of this application more clearly, the following briefly introduces the accompanying drawings required for describing the embodiments. Apparently, the accompanying drawings in the following description show merely some embodiments of this application, and a person of ordinary skill in the art may still derive other drawings from these accompanying drawings without creative efforts.

FIG. 1 is a schematic diagram of a display device according to a preferred embodiment of the present disclosure.

Reference character:

| | |
|---|---|
| 100: Display device; | 101: Bending area; |
| 102: Non-bending area; | |
| 1: Backplate; | 2: Display panel; |
| 3: Polarizer; | 4: Protective layer; |
| 5: Adhesive layer; | 6: Buffer layer; |
| 7: Supportive layer; | 8: Sealing layer; |
| 71: Hole | |

### DETAILED DESCRIPTION OF THE EMBODIMENTS

To help a person skilled in the art better understand the solutions of the present disclosure, the following clearly and completely describes the technical solutions in the embodiments of the present invention with reference to the accompanying drawings in the embodiments of the present invention. Apparently, the described embodiments are a part rather than all of the embodiments of the present invention. All other embodiments obtained by a person of ordinary skill in the art based on the embodiments of the present invention without creative efforts shall fall within the protection scope of the present disclosure.

The directional terms mentioned in the disclosure, such as “upper”, “lower”, “front”, “back”, “left”, “right”, “inner”, “outer”, “side”, etc., are only the directions in the drawings and the directional terms used herein are used to explain and illustrate the present disclosure, but are not used to limit the protection scope of the present disclosure.

In the drawings, components with the same structure are denoted by the same numerals, and components with similar structures or functions are denoted by similar numerals. In addition, in order to facilitate understanding and description, the size and the thickness of each component shown in the drawings are arbitrarily shown, and the present disclosure does not limit the size and the thickness of each component.

### EXAMPLE 1

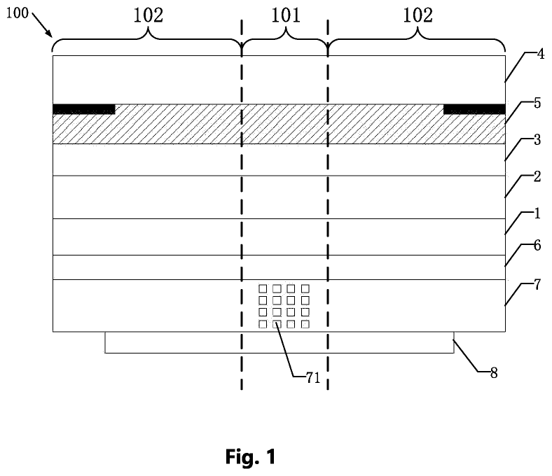

FIG. 1 is a schematic diagram of a display device 100 according to a preferred embodiment of the present disclosure. The display device 100 includes a bending area 101 and non-bending area 102. The display device 100 includes the two non-bending areas 102. The two non-bending areas 102 are arranged at both sides of the bending area 101, respectively.

As shown in FIG. 1, The display device 100 includes a backplate 1, a display panel 2, a polarizer 3, a protective layer 4, an adhesive layer 5, a buffer layer 6, a supportive layer 7, and a sealing layer 8.

The backplate 1 is a flexible backplate. A material for the backplate 1 includes polyimide (PI), polycarbonate (PC), polyethylene terephthalate (PET or PETE), or one or more polyethylene naphthalate (PEN). So the backplate 1 is impact-resistant and bendable better.

The display panel 2 is arranged on the backplate 1. The display panel 2 is either an organic light-emitting display panel or a liquid crystal display panel.

The polarizer 3 is disposed on one side of the display panel 2 away from the backplate 1. The polarizer 3 is a polymer film layer with features of high transmission, high polarized optical characteristics, high temperature, and high humidity.

The protective layer 4 is disposed on one side of the polarizer 3 away from the backplate 1. The protective layer 4 is a plastic film. A material for the protective layer 4 includes polyethylene terephthalate (PET or PETE), polyimide (PI), polyethylene (PE), or acrylic. So the protective layer 4 has good optical, scratch-resistant, and anti-wear properties, which can well protect a membrane layer of the protective layer 4.

The thickness of the protective layer 4 ranges from 30 to 150 micrometers (um). The thickness of the protective layer 4 in the present embodiment is 50 um. In other preferred embodiments of the present disclosure, the thickness of a protective layer 4 may be 30 micrometers (um), 80 um, 100 um, 150 um, etc.

The adhesive layer 5 is disposed between the protective layer 4 and the polarizer 3. One side of the adhesive layer 5 near the backplate 1 is attached to the polarizer 3 away from the backplate 1. One side of the adhesive layer 5 away from the backplate 1 is attached to the protective layer 4 near the backplate 1.

TABLE 1

| | | falling-ball | falling-pencil | |
|---|---|---|---|---|
| | | performance | Performance | |
| | | (the bending | (the bending | |
| index\type | weight/g | area)/cm | area)/cm | yield rate |
| the stack in the | 36.4 | 2.2 | 2 | 76 |
| present | | | | |
| disclosure | | | | |
| CPI stack | 46.6 | 2 | 2 | 69 |
| UTG stack | 47 | 2.5 | 5 | 65 |

Please refer to Table 1. The colorless polyimide (CPI) stack is that the CPI is arranged between the adhesive layer 5 and the protective layer 4, and the ultra-thin glass (UTG) stack is that the UTG is disposed between the adhesive layer 5 and the protective layer 4. As shown in Table 1, the plastic glass cover (colorless polyimide, CPI) and the ultra-thin glass (UTG) used in the display device of the related art are removed and are not utilized in the display device 100 proposed by the present disclosure. The difference in the falling-ball performance and the falling-pencil performance between the display device 100 proposed by the present disclosure and the CPI stack or the UTG stack is not obvious while the weight the display device 100 proposed by the present disclosure is much lower than that of the CPI stack and that of the UTG stack. Besides, the yield rate of the display device 100 proposed by the present disclosure is higher than that of the CPI stack and that of the UTG stack.

Therefore, the display device of the present disclosure can increase the yield rate of the display device and reduce the weight of the display device on the basis of satisfaction of the requirement of the falling-ball and falling-pencil performance. It is also possible to reduce the cost on the material for the display device 100, to simplify the fabrication process of the display device 100, to improve the production efficiency of the display device 100, to reduce the production cost of the display device 100, and further, the price of the display device 100 is lowered. Accordingly, more and more consumers accept the display device 100 proposed by the present embodiment, and market share increases naturally.

The adhesive layer 5 is an optical adhesive with features of colorlessness and transparency, good light transmission, high cement strength, and small induced contraction.

The buffer layer 6 is disposed on one side of the backplate 1 away from the display panel 2. A material for the buffer layer 6 includes foam, polyimide (PI), polyethylene terephthalate (PET or PETE), or one or more optical adhesive(s). The buffer layer 6 is primarily configured to buffer.

The supportive layer 7 is disposed on one side of the buffer layer 6 away from the display panel 1 and primarily configured to enhance the balance and fitness of the display device 100. The supportive layer 7 is a special thin steel plate, which is mainly made of manganese (Mn). The supportive layer 7 is fabricated by the special processes of annealing, tempering, etc., so the toughness and strength of the supportive layer 7 is excellent. The supportive layer 7 is made of a stainless steel plate (SUS) in the present embodiment.

A plurality of holes 71 are disposed on the supportive layer 7 for the bending area 101. Thereby, the ductility of the display device 100 can be improved as a whole to ensure the adaptability and coordination for deformation between the supportive layer 7 for the display device 100 and other film layers. Further, other benefits are demonstrated that the bending performance of the display device 100 is improved, the degaunting and fracture risk between the film layers is reduced, the service life of the display device 100 is prolonged, and the yield rate of the product is increased.

The sealing layer 8 covers the supportive layer 7 for the bending area 101 away from the backplate 1 and extends to cover the supportive layer 7 for the non-bending area 102 away from the backplate 1. The sealing layer 8 is primarily configured to protect the supportive layer 7.

A display device provided by the present disclosure has been introduced in detail above. Specific examples are used herein to illustrate the principles and implementation methods of the present disclosure. The description of the above embodiments is only used to help understand the method and its core of the present disclosure. At the same time, for those skilled in the art, there will be changes in the specific implementation and application scope based on the ideas of the present application. In summary, the content of the present description should not be understood as a limitation of the present application.

What is claimed is:

1. A display device, comprising:
a backplate;
a display panel, disposed on the backplate;
a polarizer, disposed on a side of the display panel away from the backplate;
a protective layer, disposed on a side of the polarizer away from the backplate; and
an adhesive layer, disposed between the protective layer and the polarizer;
wherein a side of the adhesive layer near the backplate is attached to the polarizer away from the backplate; a side of the adhesive layer away from the backplate is attached to the protective layer near the backplate.

2. The display device according to claim 1, wherein the protective layer is a plastic film layer.

3. The display device according to claim 2, wherein a material for the protective layer comprises polyethylene terephthalate (PET or PETE), polyimide (PI), polyethylene (PE), or acrylic.

4. The display device according to claim 1, wherein the thickness of the protective layer ranges from 30 to 150 micrometers (um).

5. The display device according to claim 1, wherein the adhesive layer is an optical adhesive.

6. The display device according to claim 1, wherein the display panel is either an organic light-emitting display panel or a liquid crystal display panel.

7. The display device according to claim 1, wherein, the display device further comprises:
a buffer layer, disposed on a side of the backplate away from the display panel; and
a supportive layer, disposed on a side of the buffer layer away from the display panel.

8. The display device according to claim 7, wherein the display device comprises a bending area and non-bending area;
a plurality of holes are disposed on the supportive layer for the bending area.

9. The display device according to claim 8, wherein the display device further comprises:
a sealing layer, covering the supportive layer for the bending area away from the backplate and extending to cover the supportive layer for the non-bending area away from the backplate.

10. The display device according to claim 7, wherein a material for the buffer layer is selected from foam, polyimide (PI), polyethylene terephthalate (PET), and an optical adhesive.
